(19) United States
(12) Patent Application Publication
(10) Pub. No.: US 2026/0358375 A1
(43) Pub. Date: Nov. 12, 2026

(54) MEMBRANE PROBE CARD

(71) Applicant: XINGR TECHNOLOGIES (ZHEJIANG) LIMITED, Jinhua City (CN)

(72) Inventors: Choon Leong LOU, Singapore (SG); Ho Yeh CHEN, Zhubei City (TW); Sheng-Hao CHANG, Kaohsiung City (TW); Yuan Feng CHEN, Hsinchu City (TW)

(21) Appl. No.: 19/553,166

(22) Filed: Feb. 27, 2026

(30) Foreign Application Priority Data
Apr. 14, 2025 (CN) 202510461303.1

(51) Int. Cl. G01R 1/073; G01R 1/067

(52) U.S. Cl. CPC G01R 1/0735; G01R 1/06716

(57) ABSTRACT

The present disclosure relates to the field of chip testing, in particular to a membrane probe card. The membrane probe card comprises a connecting member, a flexible membrane, a fixing member, a conductive member, a conductive layer and a plurality of probes; a lateral part of the flexible membrane is attached to a bottom surface of the connecting member by means of the fixing member, the conductive layer is arranged on a top surface of the flexible membrane, mounted to the connecting member and located above the lateral part of the flexible membrane, a lateral part of the conductive layer is located between the conductive member and the flexible membrane and in contact and electrically connected with the conductive member, the plurality of probes are mounted at intervals on the bottom surface of a middle part of the flexible membrane, and the probes are electrically connected with the conductive layer. Since a conductive connection is realized between the lateral part of the conductive layer and the conductive member in a gap-free contact manner, no solder joint exists between the lateral part of the conductive layer and the conductive member, thus the electrical signal will not be subjected to transient impedance change resulted from the existence of the solder joint in the signal transmission process, and signal reflection and leakage of the electrical signal are effectively prevented.

### CROSS REFERENCE TO RELATED APPLICATION

This application claims priority under 35 U.S.C. § 119(a) to Chinese Patent Application No. 202510461303.1, filed on Apr. 14, 2025, which is incorporated by reference.

### FIELD

The present disclosure relates to the field of chip testing, in particular to a membrane probe card.

### BACKGROUND

In an existing test probe card, a conductive member is mounted and fixed to a flexible membrane by soldering, and a conductive layer on the flexible membrane is conductively connected to the conductive member. However, when an electrical signal from the conductive layer passes through the solder joint between the flexible membrane and the conductive member, signal reflection and leakage will occur owing to sudden increase of the impedance at the solder joint, resulting in signal loss and compromised precision of the electrical signal from the conductive layer.

### SUMMARY

The object of the present disclosure is to overcome the problem of signal reflection and leakage of the electrical signal owing to the solder joint between the conductive layer and the conductive member in the prior art.

In order to achieve the above object, the present disclosure provides a membrane probe card, which comprises a connecting member, a flexible membrane, a fixing member, a conductive member, a conductive layer and a plurality of probes; a lateral part of the flexible membrane is attached to a bottom surface of the connecting member by means of the fixing member, the conductive layer is arranged on a top surface of the flexible membrane, mounted to the connecting member and located above the lateral part of the flexible membrane, a lateral part of the conductive layer is located between the conductive member and the flexible membrane and in contact and electrically connected with the conductive member, the plurality of probes are mounted at intervals on the bottom surface of a middle part of the flexible membrane, and the probes are electrically connected with the conductive layer.

In some embodiments, the conductive member is provided with an outer lateral edge that faces away from the middle part of the flexible membrane, a plane where the outer lateral edge is located is a signal boundary, and the conductive layer is arranged not to exceed the signal boundary.

In some embodiments, the conductive layer extends in the direction of extension of the flexible membrane and is attached to the top surface of the flexible membrane.

In some embodiments, the top surface of the lateral part of the conductive layer is attached to the bottom surface of the conductive member.

In some embodiments, the conductive layer consists of conductive traces of the flexible membrane.

In some embodiments, the fixing member passes through the flexible membrane and fixes the flexible membrane to the bottom surface of the connecting member by locking or soldering.

In some embodiments, the fixing member is separated from the conductive layer or connected with the conductive layer in an insulated manner.

In some embodiments, the connecting member is provided with a first connecting lateral part that faces the middle part of the flexible membrane and a second connecting lateral part that faces away from the middle part of the flexible membrane, the conductive member is located between the first connecting lateral part and the second connecting lateral part, and the first connecting lateral part and the second connecting lateral part are respectively provided with at least one fixing member, and the fixing member arranged on the first connecting lateral part and the fixing member arranged on the second connecting lateral part are configured to tension and fix the lateral part of the flexible membrane.

In some embodiments, the spacing between the conductive member and the fixing member on the first connecting lateral part is a first spacing, the spacing between the conductive member and the fixing member on the second connecting lateral part is a second spacing, and the first spacing is greater than the second spacing; and/or the diameter of the fixing member on the first connecting lateral part is greater than the diameter of the fixing member on the second connecting lateral part.

In some embodiments, the bottom surface of the flexible membrane is provided with a grounding layer for shielding off interference signals.

In some embodiments, the grounding layer is attached to the bottom surface of the flexible membrane and extends in the direction of extension of the flexible membrane.

In some embodiments, the grounding layer comprises a first extension part extending from a middle edge of the flexible membrane to the lateral part of the flexible membrane.

In some embodiments, the grounding layer comprises a second extension part extending along the middle part of the flexible membrane, and the second extension part is provided with a plurality of clearance holes extending therethrough, the plurality of probes pass through the clearance holes in one-to-one correspondence, and the second extension part is electrically connected with the first extension part.

In some embodiments, the membrane probe card further comprises a bearing mechanism, which is located below the lateral part of the flexible membrane and attached to the bottom surface of the lateral part of the flexible membrane, and is fixedly connected to the connecting member.

In some embodiments, the bearing mechanism comprises a bearing base, a top surface of the bearing base is attached to the bottom surface of the lateral part of the flexible membrane, the bearing base is fixedly connected to the connecting member by means of the fixing member, and the fixing member extends to the middle part of the bearing base in the thickness direction.

In some embodiments, the top of the bearing base is provided with a mounting groove, an elastic member is arranged in the mounting groove and located directly below the conductive member, a top surface of the elastic member is in contact with the bottom surface of the lateral part of the flexible membrane, and the elastic member can apply elastic force to the lateral part of the flexible membrane to force the lateral part of the conductive layer and the conductive member to closely attach to each other.

The above technical scheme of the present disclosure has the following beneficial effects:

The lateral part of the flexible membrane is fixed to the bottom surface of the connecting member by means of the fixing member. The conductive layer is arranged on the top surface of the flexible membrane, the lateral part of the conductive layer is located between the conductive member and the flexible membrane, and the lateral part of the conductive layer can be firmly fixed between the conductive member and the flexible membrane along with the lateral part of the flexible membrane. The probes are electrically connected with the conductive layer, and the lateral part of the conductive layer is electrically connected with the conductive member, thereby the probes, the conductive layer and the conductive member form an electrical signal transmission path. Since the conductive connection between the lateral part of the conductive layer and the conductive member is realized in a gap-free contact manner instead of soldering, no solder joint exists between the lateral part of the conductive layer and the conductive member, the electrical signal will not be subjected to transient impedance change resulted from the existence of the solder joint in the transmission process, thereby signal reflection and leakage of the electrical signal are effectively prevented, the precision of the electrical signal is improved, and the testing accuracy is improved accordingly.

### BRIEF DESCRIPTION OF THE DRAWINGS

FIG. 1 is a side view of a membrane probe card.

FIG. 2 is partial side view of a membrane probe card.

FIG. 3 is a partial side view of a membrane probe card.

FIG. 4 is a partial side view of a membrane probe card.

FIG. 5 is a top view of a membrane probe card.

FIG. 6 is a top view of a membrane probe card.

### REFERENCE NUMERALS

1—connecting member; 11—first connecting lateral part; 12—second connecting lateral part;
2—flexible membrane;
3—fixing member; 31—first fixing member; 32—second fixing member;
4—conductive member; 41—signal boundary;
5—conductive layer;
6—probe;
7—grounding layer; 71—first extension part; 72—second extension part; 73 clearance hole;
8—bearing mechanism; 81—bearing base; 82—elastic member.

### DETAILED DESCRIPTION

The features and exemplary embodiments in various aspects of the present disclosure will be described in detail below. The present disclosure will be further detailed in specific embodiments with reference to the accompanying drawings, to make the object, technical scheme, and advantages of the present disclosure understood more clearly. It may be understood that the embodiments described herein are only intended to explain the present disclosure, but are not intended to limit the present disclosure in any way. It will be apparent to those skilled in the art that the present disclosure can be implemented without some of the specific details. The following description of the embodiments is only intended to provide a better understanding on the present disclosure by showing examples of the present disclosure.

In an existing test probe card, a conductive member is mounted and fixed to a flexible membrane by soldering, and a conductive layer on the flexible membrane is conductively connected with the conductive member, so that an electrical signal can be transmitted from the conductive layer to the conductive member, and the electrical signal passes through a solder joint between the conductive layer and the conductive member. However, there are material differences between the conductive layer and the conductive member and the solder joint, and the surface of the solder joint often involves sudden structural changes, and a transient impedance change occurs at the solder joint at least owing to these reasons. When the electrical signal is transmitted along the transmission path, it will be subjected to transient impedance at every position in the transmission path; if the transient impedance against the electrical signal is constant, the electrical signal will be transmitted stably; however, if the transient impedance against the electrical signal suddenly changes somewhere, the electrical signal will be reflected and leak, resulting in the compromised precision of the electrical signal. Since a transient impedance change exists at the solder joint, the electrical signal is often reflected and leaks at the solder joint. As a result, the precision of the electrical signal is compromised, and the testing accuracy is decreased. Based on that background, the present disclosure proposes a solution.

As shown in FIGS. 1 to 4, the present disclosure provides a membrane probe card, which comprises a connecting member 1, a flexible membrane 2, a fixing member 3, a conductive member 4, a conductive layer 5 and a plurality of probes 6. A lateral part of the flexible membrane 2 is attached to a bottom surface of the connecting member 1 by means of the fixing member 3, and the conductive layer 5 is arranged on a top surface of the flexible membrane 2, the conductive member 4 is mounted to the connecting member 1 and located above the lateral part of the flexible membrane 2; a lateral part of the conductive layer 5 is located between the conductive member 4 and the flexible membrane 2, and the lateral part of the conductive layer 5 and the conductive member 4 are conductively connected in a gap-free manner. The plurality of probes 6 are mounted at intervals to the bottom surface of a middle part of the flexible membrane 2, and the probes 6 are electrically connected with the conductive layer 5.

Specifically, the lateral part of the flexible membrane 2 is fixed to the bottom surface of the connecting member 1 by means of the fixing member 3. The conductive layer 5 is arranged on the top surface of the flexible membrane 2, the lateral part of the conductive layer 5 is located between the conductive member 4 and the flexible membrane 2, and the lateral part of the conductive layer 5 can be firmly fixed between the conductive member 4 and the flexible membrane 2 along with the lateral part of the flexible membrane 2. The probes 6 are electrically connected with the conductive layer 5, and the lateral part of the conductive layer 5 is electrically connected with the conductive member 4, thereby the probes 6, the conductive layer 5 and the conductive member 4 form an electrical signal transmission path. Since the conductive connection between the lateral part of the conductive layer 5 and the conductive member 4 is realized in a gap-free contact manner instead of soldering, no solder joint exists between the lateral part of the conductive layer 5 and the conductive member 4, the electrical signal will not be subjected to transient impedance change resulted from the existence of the solder joint in the transmission process, thereby signal reflection and leakage of the electrical signal are effectively prevented, the precision of the electrical signal is improved, and the testing accuracy is improved accordingly.

As shown in FIGS. 1 to 4, in some embodiments, the conductive member 4 is provided with an outer lateral edge that faces away from the middle part of the flexible membrane 2, a plane where the outer lateral edge is located is a signal boundary 41, and the distribution range of the conductive layer 5 does not exceed the signal boundary 41.

Specifically, the conductive layer 5 extends toward the signal boundary 41 but doesn't exceed the signal boundary 41, thus an antenna effect or edge effect at the end of the conductive layer 5 is avoided, and signal leakage or reflection at the connection between the conductive layer 5 and the conductive member 4 is further avoided, and the electrical signal can be stably transmitted.

As shown in FIGS. 1 to 4, in some embodiments of the present disclosure, the conductive layer 5 extends in the direction of extension of the flexible membrane 2 and is attached to the top surface of the flexible membrane 2.

Specifically, the conductive layer 5 can be arranged on the top surface of the flexible membrane 2 by etching or deposition, so as to achieve close attachment between the conductive layer 5 and the flexible membrane 2. Since the conductive layer 5 is attached to the top surface of the flexible membrane 2, the position of the conductive layer 5 is relatively stable during signal testing, which is conducive to the stable transmission of the electrical signal.

In some embodiments of the present disclosure, the top surface of the lateral part of the conductive layer 5 is attached to the bottom surface of the conductive member 4, so that the spacing between the top surface of the lateral part of the conductive layer 5 and the bottom surface of the conductive member 4 is zero, thereby gap-free contact is realized.

In some embodiments of the present disclosure, the conductive layer 5 consists of conductive traces of the flexible membrane 2, and an electrical signal can be transmitted along the probes 6, the conductive layer 5 and the conductive member 4.

As shown in FIGS. 1 to 6, in some embodiments of the present disclosure, the fixing member 3 passes through the flexible membrane 2 and fixes the flexible membrane 2 to the bottom surface of the connecting member 1 by locking or soldering, so that the conductive layer 5 can be clamped and fixed between the conductive member 4 and the flexible membrane 2, thereby good gap-free contact is maintained between the conductive layer 5 and the conductive member 4.

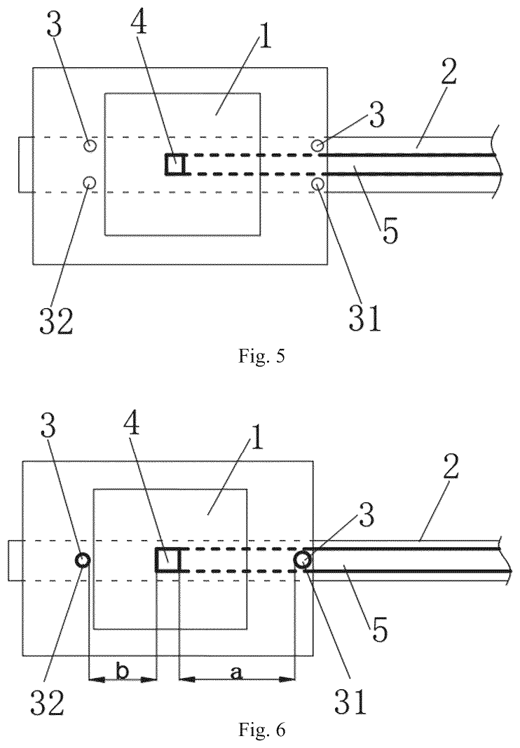

As shown in FIGS. 5 to 6, in some embodiments of the present disclosure, the fixing member 3 is separated from the conductive layer 5 or connected to the conductive layer 5 in an insulated manner, to prevent the fixing member 3 from interfering with the transmission of the electrical signal.

Specifically, the fixing member 3 may pass through the flexible membrane 2, while the fixing member 3 is separated from the conductive layer 5. Of course, alternatively, the fixing member 3 may pass through the conductive layer 5 and the flexible membrane 2, and the periphery of the fixing member 3 is wrapped with an insulating material, so as to realize an insulated connection between the fixing member 3 and the conductive layer 5.

In the process of signal testing, the probes 6 are pressed on a chip to be tested. Based on the counter force of the chip to be tested, the probes 6 drive the middle part of the flexible membrane 2 to move upward. The upward movement of the middle part of the flexible membrane 2 may lead to the movement or deformation of the lateral part of the flexible membrane 2, leading to a slight gap between the lateral part of the conductive layer 5 and the conductive member 4, and the slight gap leads to a transient impedance change at this position. However, the present disclosure can avoid this problem by means of the following scheme. As shown in FIGS. 1 to 4, in some embodiments of the present disclosure, the connecting member 1 is provided with a first connecting lateral part 11 that faces the middle part of the flexible membrane 2 and a second connecting lateral part 12 that faces away from the middle part of the flexible membrane 2, the conductive member 4 is located between the first connecting lateral part 11 and the second connecting lateral part 12, and the first connecting lateral part 11 and the second connecting lateral part 12 are respectively provided with at least one fixing member 3, and the fixing member 3 arranged on the first connecting lateral part 11 and the fixing member 3 arranged on the second connecting lateral part 12 are configured to tension and fix the lateral part of the flexible membrane 2.

Specifically, the fixing member 3 arranged on the first connecting lateral part 11 is defined as a first fixing member 31, and the fixing member 3 arranged on the second connecting lateral part 12 is defined as a second fixing member 32. The first fixing member 31 and the second fixing member 32 can tension up and fix the lateral part of the flexible membrane 2, so that the lateral part of the flexible membrane 2 and the lateral part of the conductive layer 5 are always flat without being affected by the upward movement of the middle part of the flexible membrane 2, thereby the top surface of the lateral part of the conductive layer 5 and the bottom surface of the conductive member 4 are always maintained in good contact without a gap. Moreover, the influence of the upward movement of the middle part of the flexible membrane 2 is only transferred to the first fixing member 31 at most, and will not be further transferred to the conductive member 4.

In some embodiments, there are two first fixing members 31 and two second fixing members 32 respectively, the two first fixing members 31 are spaced apart from each other in the width direction of the conductive layer 5, and the two second fixing members 32 are spaced apart from each other in the width direction of the conductive layer 5.

As shown in FIGS. 1 to 6, in some embodiments of the present disclosure, the spacing between the conductive member 4 and the fixing member 3 on the first connecting lateral part 11 is a first spacing a, the spacing between the conductive member 4 and the fixing member 3 on the second connecting lateral part 12 is a second spacing b, and the first spacing a is greater than the second spacing b.

Specifically, the fixing member 3 arranged on the first connecting lateral part 11 is defined as a first fixing member 31, and the fixing member 3 arranged on the second connecting lateral part 12 is defined as a second fixing member 32. With this arrangement, the first fixing member 31 is away from the conductive member 4, which helps to keep the influence of the upward movement of the middle part of the flexible membrane 2 away from the conductive member 4 as far as possible; besides, the second fixing member 32 is away from the conductive member 4, which helps to keep gap-free contact between the conductive member 4 and the lateral part of the conductive layer 5.

In some embodiments of the present disclosure, the diameter of the fixing member 3 on the first connecting lateral part 11 is greater than that of the fixing member 3 on the second connecting lateral part 12.

Specifically, the fixing member 3 arranged on the first connecting lateral part 11 is defined as a first fixing member 31, and the fixing member 3 arranged on the second connecting lateral part 12 is defined as a second fixing member 32. By configuring the diameter of the first fixing member 31 to be greater than that of the second fixing member 32, the fixing effect of the flexible membrane 2 at the first fixing member 31 is better, and the lateral part of the flexible membrane 2 is prevented from being influenced by the middle part thereof more effectively.

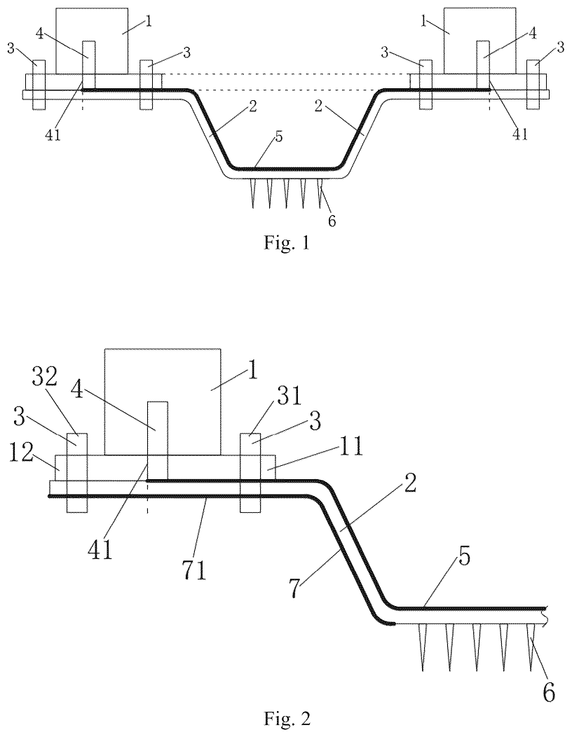

As shown in FIGS. 2 to 4, in some embodiments of the present disclosure, the bottom surface of the flexible membrane 2 is provided with a grounding layer 7 for shielding off interference signals. The grounding layer 7 can shield off the interference signals in the test area and prevent the electrical signal in the probes 6, the conductive layer 5 and the conductive member 4 from being interfered.

As shown in FIGS. 2 to 4, in some embodiments of the present disclosure, the grounding layer 7 is attached to the bottom surface of the flexible membrane 2 and extends in the direction of extension of the flexible membrane 2.

Specifically, the grounding layer 7 can be arranged on the bottom surface of the flexible membrane 2 by etching or deposition, so that the grounding layer 7 and the flexible membrane 2 can be attached to each other well.

As shown in FIGS. 2 to 4, in some embodiments, the grounding layer 7 comprises a first extension part 71 extending from a middle edge of the flexible membrane 2 to the lateral part of the flexible membrane 2. The first extension part 71 has a great extension range and can effectively shield off interference signals.

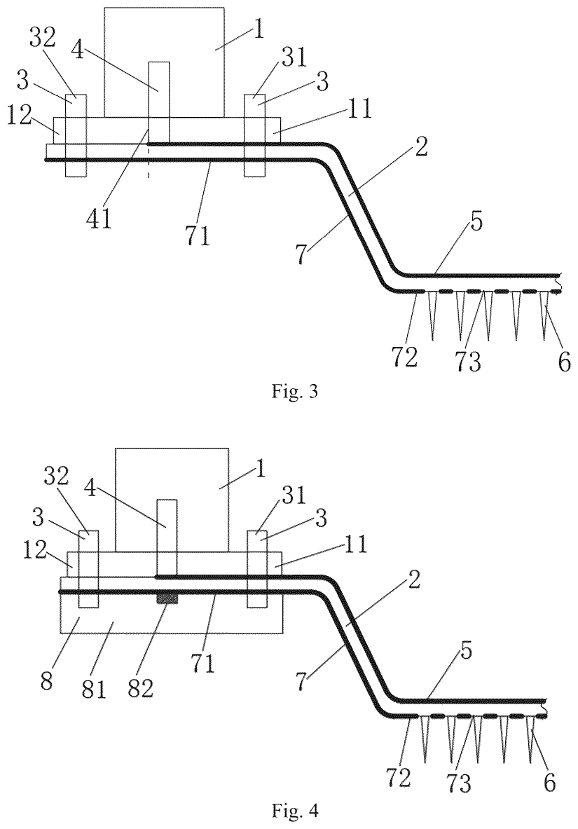

As shown in FIGS. 3 and 4, in some embodiments, the grounding layer 7 comprises a second extension part 72 extending along the middle part of the flexible membrane 2, and the second extension part 72 is provided with a plurality of clearance holes 73 extending therethrough, the plurality of probes 6 pass through the clearance holes 73 in one-to-one correspondence, and the second extension part 72 is electrically connected with the first extension part 71. The second extension part 72 can shield the middle part of the flexible membrane 2 from interference signals, and the second extension part 72 and the first extension part 71 can shield the conductive layer 5 from all interference signals.

Of course, insulation is formed between the grounding layer 7 and the probes 6. For example, the diameters of the clearance holes 73 are larger than the diameters of the probes 6, so that the grounding layer 7 is separated from the probes 6. For another example, the walls of the clearance hole 73 are provided with an insulating material, which surrounds the probes 6.

As shown in FIG. 4, in some embodiments of the present disclosure, the membrane probe card further comprises a bearing mechanism 8, which is located below the lateral part of the flexible membrane 2 and attached to the bottom surface of the lateral part of the flexible membrane 2, and is fixedly connected to the connecting member 1.

Specifically, the bearing mechanism 8 is connected to the connecting member 1 by means of the fixing members 3 (e.g., the first fixing member 31 and the second fixing member 32), and the bearing mechanism 8 is located below the connecting member 1. The bearing mechanism 8 can properly press or support the lateral part of the flexible membrane 2, so that the lateral part of the flexible membrane 2 is kept flat. On one hand, it is convenient for the first fixing member 31 and the second fixing member 32 to tension and fix the lateral part of the flexible membrane 2; on the other hand, the lateral part of the flexible membrane 2 is prevented from bending and deforming under its own weight.

In some embodiments, the bearing mechanism 8 can be connected to the connecting member 1 by fasteners or clamps, so that the flexible membrane 2 can be detached.

In some embodiments, the bearing mechanism 8 may be a frame structure or a hollow shell structure formed by a plurality of bars connected together. There is no particular restriction on the specific structure of the bearing mechanism 8 in the present disclosure.

As shown in FIG. 4, in some embodiments of the present disclosure, the bearing mechanism 8 comprises a bearing base 81, a top surface of the bearing base 81 is attached to the bottom surface of the lateral part of the flexible membrane 2, the bearing base 81 is fixedly connected to the connecting member 1 by means of the fixing member 3, and the fixing member 3 extends to the middle part of the bearing base 81 in the thickness direction.

Specifically, the bearing base 81 is connected to the connecting member 1 by means of the fixing members 3 (e.g., the first fixing member 31 and the second fixing member 32), and the bearing base 81 is located below the connecting member 1. The top surface of the bearing base 81 is flat, which is convenient to press or support the lateral part of the flexible membrane 2.

In some embodiments, the connection between the fixing member 3 and the bearing base 81 can be realized by means of a threaded connection or interference fit, so that the flexible membrane 2 can be easily detached. Of course, other connection forms may also be used between the fixing member 3 and the bearing base 81. There is no particular restriction on the specific form of connection in the present disclosure.

As shown in FIG. 4, in some embodiments of the present disclosure, the top of the bearing base 81 is provided with a mounting groove, an elastic member 82 is arranged in the mounting groove and located directly below the conductive member 4, a top surface of the elastic member 82 is in contact with the bottom surface of the lateral part of the flexible membrane 2, and the elastic member 82 can apply elastic force to the lateral part of the flexible membrane 2 to force the lateral part of the conductive layer 5 and the conductive member 4 to closely attach to each other.

Specifically, the elastic member 82 mounted in the mounting groove is in a compressed state, and the top surface of the elastic member 82 is flush with the top surface of the bearing base 81, so as to prevent a gap between the bearing base 81 and the lateral part of the flexible membrane 2. The elastic member 82 can apply elastic force to the lateral part of the flexible membrane 2, so that the lateral part of the conductive layer 5 and the conductive member 4 are closely attached to each other, thereby the lateral part of the conductive layer 5 and the conductive member 4 are kept in gap-free contact.

In some embodiments, the elastic member 82 may be an elastic plastic member, rubber member or metal member, for example, a solid plastic block, a hollow rubber block or a coil spring, etc. There is not particular restriction on the specific configuration of the elastic member 82 in the present disclosure. In some embodiments, in the case that the elastic member 82 is a metal member, the part of the elastic member 82 that contacts the flexible membrane 2 is further provided with an insulating layer.

In some embodiments, as shown in FIG. 4, the top surface of the bearing base 81 is attached to the bottom surface of the first extension part 71 of the ground plane 7.

In some embodiments, as shown in FIG. 4, the top surface of the elastic member 82 is in contact with the bottom surface of the first extension part 71 of the grounding layer 7.

While the principle and embodiments of the present disclosure are described herein in specific examples, the description of those examples is only intended to assist in understanding the method and core idea of the present disclosure. The above embodiments are only some preferred embodiments of the present disclosure. It may be noted that objectively numerous specific structures may exist though the literal expression is limited. Those having ordinary skills in the art can make various improvements, modifications or variations, and combine the above-mentioned technical features in appropriate ways, without departing from the principle of the present disclosure; however, those improvements, modifications, variations, or combinations, or direct application of the inventive concept and technical scheme of the present disclosure to other scenarios without improvement shall be deemed as falling in the scope of protection of the present disclosure.

What is claimed is:

1. A membrane probe card, comprising a connecting member, a flexible membrane, a fixing member, a conductive member, a conductive layer and a plurality of probes,
wherein a lateral part of the flexible membrane is attached to a bottom surface of the connecting member by means of the fixing member; the conductive layer is arranged on a top surface of the flexible membrane, the conductive member is mounted to the connecting member and located above the lateral part of the flexible membrane; a lateral part of the conductive layer is located between the conductive member and the flexible membrane, and is in contact and conductively connected with the conductive member; and the plurality of probes are mounted at intervals to the bottom surface of a middle part of the flexible membrane, and the probes are conductively connected with the conductive layer.

2. The membrane probe card of claim 1, wherein the conductive member is provided with an outer lateral edge, which faces away from the middle part of the flexible membrane, a plane where the outer lateral edge is located is a signal boundary, and the conductive layer is arranged not to exceed the signal boundary.

3. The membrane probe card of claim 1, wherein the conductive layer extends in a direction of extension of the flexible membrane and is attached to the top surface of the flexible membrane.

4. The membrane probe card of claim 3, wherein the top surface of the lateral part of the conductive layer is attached to the bottom surface of the conductive member.

5. The membrane probe card of claim 1, wherein the conductive layer consists of conductive traces of the flexible membrane.

6. The membrane probe card of claim 1, wherein the fixing member passes through the flexible membrane and fixes the flexible membrane to the bottom surface of the connecting member by locking or soldering.

7. The membrane probe card of claim 1, wherein the fixing member and the conductive layer are separated from each other or connected in an insulated manner.

8. The membrane probe card of claim 1, wherein the connecting member is provided with a first connecting lateral part that faces the middle part of the flexible membrane and a second connecting lateral part that faces away from the middle part of the flexible membrane, the conductive member is located between the first connecting lateral part and the second connecting lateral part, the first connecting lateral part and the second connecting lateral part are respectively provided with at least one fixing member, and the fixing member arranged on the first connecting lateral part and the fixing member arranged on the second connecting lateral part are configured to tension and fix the lateral part of the flexible membrane.

9. The membrane probe card of claim 8, wherein the spacing between the conductive member and the fixing member on the first connecting lateral part is a first spacing, and the spacing between the conductive member and the fixing member on the second connecting lateral part is a second spacing, and the first spacing is greater than the second spacing;
and/or the diameter of the fixing member on the first connecting lateral part is greater than the diameter of the fixing member on the second connecting lateral part.

10. The membrane probe card of claim 1, wherein the bottom surface of the flexible membrane is provided with a grounding layer for shielding off interference signals.

11. The membrane probe card of claim 10, wherein the grounding layer is attached to the bottom surface of the flexible membrane and extends in the direction of extension of the flexible membrane.

12. The membrane probe card of claim 11, wherein the grounding layer comprises a first extension part extending from a middle edge of the flexible membrane to the lateral part of the flexible membrane.

13. The membrane probe card of claim 12, wherein the grounding layer comprises a second extension part extending along the middle part of the flexible membrane, and the second extension part is provided with a plurality of clearance holes extending therethrough, the plurality of probes pass through the clearance holes in one-to-one correspondence, and the second extension part is electrically connected with the first extension part.

14. The membrane probe card of claim 1, further comprising a bearing mechanism, which is located below the lateral part of the flexible membrane and attached to the bottom surface of the lateral part of the flexible membrane, and is fixedly connected to the connecting member.

15. The membrane probe card of claim 14, wherein the bearing mechanism comprises a bearing base, a top surface of the bearing base is attached to the bottom surface of the lateral part of the flexible membrane, the bearing base is fixedly connected to the connecting member by means of the fixing member, and the fixing member extends to the middle part of the bearing base in the thickness direction.

16. The membrane probe card of claim 15, wherein the top of the bearing base is provided with a mounting groove, and an elastic member is arranged in the mounting groove and located directly below the conductive member, a top surface of the elastic member is in contact with the bottom surface of the lateral part of the flexible membrane, and the elastic member can apply elastic force to the lateral part of the flexible membrane to force the lateral part of the conductive layer and the conductive member to closely attach to each other.
